(19) United States
(12) Patent Application Publication
(10) Pub. No.: US 2026/0143618 A1
(43) Pub. Date: May 21, 2026

(54) SYSTEM FOR PRESSING A SERVER ONTO A METAL BLOCK

(71) Applicant: QARNOT COMPUTING, Montrouge (FR)

(72) Inventors: Louis MIKOLAJCZAK, Clamart (FR); Paul BENOIT, Paris (FR); Clément PELLEGRINI, Montrouge (FR)

(21) Appl. No.: 18/872,571

(22) PCT Filed: May 23, 2023
(86) PCT No.: PCT/EP2023/063806

§ 371 Date: Jul. 17, 2025

(30) Foreign Application Priority Data
Jun. 28, 2022 (FR) FR2206481

(51) Int. Cl. H05K 7/14

(52) U.S. Cl. CPC H05K 7/1489

(57) ABSTRACT

A system for pressing an electronic board onto a metal block provided with one or more side support members includes a cradle housing the electronic board intended to be pressed against a surface of the metal block, the cradle including side walls provided with straight grooves capable of engaging with the support members of the metal block when the cradle is pressed against the surface of the metal block, a slide arranged on the back of the cradle, this slide including side walls provided with oblique grooves capable of engaging with the support members; these oblique grooves being arranged in such a way that a longitudinal sliding movement of the slide relative to the cradle moves the cradle sideways so as to press the electronic board onto the metal block, at least one cam handle for applying pressure to press the electronic board against the metal block.

### TECHNICAL FIELD

The present invention relates to a system for pressing a server onto a metal block. A particularly interesting application is in the field of digital boilers, wherein the heat generated by running servers is used to heat water circulating in pipes. The invention can also be applied to the cooling of servers used in data centers.

### PRIOR ART

Heat sinks are generally secured by screws or springs, or both.

Graphics card coolers based on copper heat pipes are well known. Such copper heat pipes are attached in finned radiators, which in turn are screwed to the electronic board. Screw fastening can generate physical stresses that can damage the electronic board.

The screw and spring assembly can move without guaranteeing the positioning of the server in relation to the cooler.

Immersion cooling systems are also known wherein servers are immersed in a coolant. Such systems are complex to implement. There are also watercooling systems, wherein water is circulated through a waterblock placed on the component to be cooled. These devices can also be used with other heat transfer fluids.

The aim of the present invention is a new pressing system which is efficient and repeatable, even during maintenance operations.

The invention also relates to at a new, quick and easy pressing system.

### DISCLOSURE OF THE INVENTION

At least one of the above-mentioned objectives is achieved with a system for pressing an electronic board onto a metal block provided with one or more side support members. The system according to the invention comprises:
a cradle housing the electronic board intended to be pressed against a surface of the metal block, the cradle comprising side walls provided with straight grooves capable of engaging with the support members of the metal block when the cradle is pressed against the surface of the metal block,
a slide arranged on the back of the cradle, this slide comprising side walls provided with oblique grooves capable of engaging with the support members; these oblique grooves being arranged in such a way that a longitudinal sliding movement of the slide relative to the cradle moves the cradle sideways so as to press the electronic board onto the metal block,
at least one cam handle for applying pressure to press the electronic board against the metal block.

“Electronic board” refers to a server-type electronic board or a printed circuit whereupon electronic data processing and/or storage components, removable components such as RAM strips, a power supply or any other component capable of generating heat are attached. The electronic processing components may comprise microprocessors, graphics processors or the like. The electronic storage components may comprise SSD (solid-state drive) or other types of memory.

The metal block may be in the form of a central, generally parallelepiped column.

With the system according to the invention, the electronic board can be easily attached to the metal block and removed without tools. This provides a significant advantage in terms of reliability, repeatability and maintenance.

A cam-operated handle is used to ensure effective, firm pressing. By locking the cam handle, pressure is exerted on the cradle, pressing the electronic board against the metal block. When locked, the slide is held stationary by the support members inserted in the oblique grooves. The handle is also used to carry and position the cradle. It also plays an ergonomic role.

The straight grooves ensure correct positioning of the electronic board in relation to the metal block.

The system according to the invention enables the electronic board, cradle and slide assembly to be placed by placing the inlet of the straight and oblique grooves on the metal block support members. The slide can be moved longitudinally in a direction perpendicular to the direction of the straight grooves; this movement causes the support members to slide inside the oblique grooves, bringing the back of the slide closer to the metal block, and as a result the electronic board and cradle assembly closer to the metal block.

The locking of the cam handle holds the electronic board in place against the metal block. Cam sizing defines the pressure applied to the cradle.

Pressing the electronic board against the metal block ensures that the heat generated by the electronic board is transferred to the metal block.

With this type of system, the number of actions required to press the electronic board against the metal block is limited. The pressing process is completely reversible, efficient and repeatable, ensuring reliable heat transfer even during maintenance operations, especially on site.

According to an embodiment of the invention, the slide can comprise an opening in the back of the cradle so that a locking of the cam handle presses the cradle against the metal block. In other words, the cam handle bears on the stationary slide to exert force on the cradle via the opening in the back of the cradle.

The cam handle comprises a cam which can exert this force directly on the cradle via the opening in the back of the cradle.

Alternatively, the slide can comprise a spring arranged between the cam handle and the back of the cradle. In this case, the force of the cam is exerted on the cradle via the spring.

The pressure of the pressing can be adjusted according to the type and characteristics of the spring selected.

In a preferred embodiment, the spring can be a leaf capable of pressing the cradle against the metal block when the cam handle is locked.

Advantageously, the leaf can be curved, with both ends bearing directly on the back of the cradle. In other words, the spring leaf has two bearing points on the cradle. The center of the leaf may comprise a rib wherein a rod is inserted which is connected to the cam of the cam handle, the rod being outside the pivot axis of the cam handle.

With this arrangement, the cam transmits its force to the rod, which presses the spring against the cradle.

According to an embodiment of the invention, the cam handle can comprise two cams connected together by the rod, the two cams being arranged on both sides of the leaf.

In this way, the cam handle bears on two spaced-apart points of the slide, providing a degree of stability during locking.

According to the invention, the cam handle can comprise a pivot axis contained in a plane parallel to the back of the cradle, the handle being pivotally connected to eyelets on the slide.

According to an advantageous feature of the invention, the slide can have a “U”-shaped cross-section suitable for nesting the cradle into this slide.

According to another advantageous feature of the invention, the cradle can have a “U”-shaped cross-section for housing the electronic board and for nesting the metal block into this cradle.

In addition in particular to all the above, the oblique groove can be an opening in the side wall of the slide, this opening going from a point on the wall, away from the free edge, down obliquely in a linear or non-linear manner until it opens onto the free edge of the side wall of the slide.

Such an oblique arrangement brings the slide closer to the metal block as the slide slides, bringing the support members up inside the oblique grooves.

Ideally, the oblique grooves provide a stress-free area at the inlet for receiving the support members. Then, the oblique part of the oblique grooves can be linear or have waves to facilitate the insertion of the support members.

In addition to the above, the straight groove can be an opening in the side wall of the cradle, this opening being perpendicular to a plane containing the electronic board and opening onto the free edge of the cradle side wall.

The plane containing the electronic board is essentially the plane of the printed circuit whereupon the electronic components making up the electronic board are attached.

According to an advantageous feature of the invention, the metal block can be a longitudinal body and the system can further comprise at least two side support members attached to the metal block but extending outside the metal block on the same line but in two opposite directions.

The metal block is a body, and the support members are outstretched arms with which the straight and oblique grooves engage.

According to an embodiment of the invention, the metal block can comprise at least one water circulation pipe for recovering heat generated by the electronic board.

In fact, the metal block can be a metal plate designed to transmit the heat generated by the electronic board to water circulation pipes. Such an arrangement enables heat generated in electronic boards or computer servers to be dissipated, or transferred to water in a boiler.

Advantageously, the system according to the invention can be used on a vertically arranged metal block. Ideally, several metal blocks equipped with electronic boards pressed according to the invention and distributed over an array in a boiler can be envisaged. “Array” refers to a water circuit made with a serpentine copper pipe and metal blocks arranged vertically on straight vertical portions of the serpentine, the whole constituting a vertical panel.

An array structure also facilitates access to the electronic boards on both sides of the block, without cutting off water or electricity, and reduces the mobility of the electrical cables used in electronic boards.

According to an advantageous feature of the invention, the metal block can comprise a protuberance and/or a cavity able to match the external shape of an electronic component contained on the electronic board.

Advantageously, the metal block can be made up of at least two parts, a stationary block and a modular block adapted to a given electronic board. In other words, several modular blocks are provided, each of which can be attached to the stationary block. The stationary blocks have the holes tapped according to a matrix, and the modular blocks have the holes arranged according to the same matrix. Each modular block comprises recesses and/or protuberances adapted to the electronic components of a given electronic board.

According to another aspect of the invention, a method is proposed for attaching an electronic board to a metal block, the electronic board being contained in a cradle equipped with a slide, this metal block being provided with one or more side support members. The method may also comprise the following steps:
pressing the cradle onto the metal block, the cradle comprising side walls provided with straight grooves which engage with the support members of the metal block, and the slide comprising side walls provided with oblique grooves which also engage with the support members of the metal block;
longitudinal sliding movement of the slide in relation to the cradle, so that the support members run in the oblique grooves and the electronic board is pressed against the metal block,
locking a cam handle to press the electronic board against the metal block.

The oblique grooves allow the electronic board to be correctly positioned in relation to the metal block. This positioning can be achieved without contact, before locking the handle. When a thermal paste is applied to an electronic component of the electronic board, the locking of the handle allows the electronic component to be pressed against the metal block. The sandwiched thermal paste ensures good thermal contact between the electronic component and the metal block.

### DESCRIPTION OF THE FIGURES AND EMBODIMENTS.

Other benefits and features shall become evident upon examining the detailed description of entirely non-limiting embodiments and implementations, and from the following enclosed drawings:

FIG. 1 is a schematic diagram of a general external view of the boiler according to the invention,

FIG. 2 is a schematic view of the boiler according to the invention with one side wall detached,

FIG. 3 is a schematic cross-sectional view of the top of the boiler according to the invention,

FIG. 4 is a schematic perspective view of a panel of the boiler open on the side according to the invention,

FIG. 5 is a schematic cross-sectional view of the top of the boiler according to the invention with a panel open on the side according to the invention,

FIG. 6 is a schematic view of a serpentine copper pipe loop according to the invention,

FIG. 7 is a schematic perspective view of two cradles intended to frame a metal block, both cradles being equipped with cam handles for pressing according to the invention,

FIG. 8 is a view of the assembly shown in FIG. 7 in an assembled but not yet locked position,

FIG. 9 is a view of the assembly shown in FIG. 7 in a locked position, with the handles folded down,

FIG. 10 is a schematic exploded view showing the successive layers comprising the slide, cradle, server and metal block according to the invention,

FIG. 11 is a schematic view showing the movement of the oblique groove relative to the metal block support member,

FIG. 12 is a schematic top view of a metal block around the copper pipe in the presence of a server pressed onto the metal block according to the invention,

FIG. 13 is a schematic top view of a slide on a cradle,

FIG. 14 is a schematic view showing the arrangement between the cam and the spring according to the invention,

FIG. 15 is a schematic side view of a part of the cam handle 42 showing an asymmetry of the cam according to the invention,

FIG. 16 is a schematic cross-sectional view of the cam in connection with an eyelet of the slide according to the invention,

FIG. 17 is a schematic cross-sectional view of heat pipes integrated in a modular block according to the invention,

FIG. 18 is a schematic view from above of heat pipes integrated in a modular block according to the invention, and

FIG. 19 is a schematic view of the underside of heat pipes integrated in a modular block according to the invention.

The embodiments which will be disclosed hereinafter are in no way limiting; in particular, it is possible to implement variants of the invention that comprise only a selection of the features disclosed hereinafter in isolation from the other features disclosed, if this selection of features is sufficient to confer a technical benefit or to differentiate the invention with respect to the prior art. This selection comprises at least one preferably functional feature which lacks structural details, or only has a portion of the structural details if that portion only is sufficient to confer a technical benefit or to differentiate the invention with respect to the prior state of the art.

Although the invention is not limited thereto, it will now be disclosed in the context of a digital boiler. It should be noted that the invention can also be applied to heat removal systems within data centers.

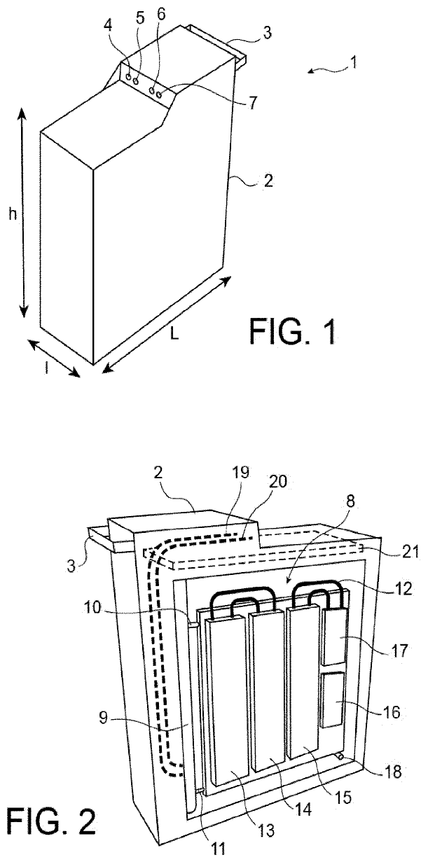

FIG. 1 is an external view of the boiler 1 according to the invention. There is a metal box 2, roughly parallelepipedic in shape. As a non-limiting example, the dimensions of the boiler can be 114 cm in length L, 35 cm in width 1 and 114 cm in height h.

A handle 3 is provided across the width of the boiler, at the top, for handling.

The upper part of the boiler comprises an indentation to accommodate inlet and outlet interfaces. We distinguish:
a water inlet 4, which can be directly connected to the water distribution network, e.g. the drinking water network,
an outlet 5 for hot water after passing through the box, which outlet is intended to supply a hot water network,
an inlet 6 for the general power supply to supply the electrical components within the boiler; this general power supply inlet 6 can be directly connected to the mains, that is, the conventional electrical network,
one or more fiber optic network connectors for data communication between the boiler and the outside world.

In the installed position, the boiler 1 is designed to be taller than it is wide.

FIG. 2 is a schematic perspective view of the boiler 1 with one side wall removed. This may be a removable wall or a door that can be opened by pivoting on hinges, not shown, attached to one of the four rims defining the opening in FIG. 2.

A panel 8 can be distinguished in the form of a vertical array positioned in a plane comprising the length and height of the box.

A stationary foot 9 made of metal or hard plastic stands vertically in the direction of the box height.

The foot 9 acts as a mast to support the panel 8 by means of two hinges 10 and 11. As a result, the panel 8 can pivot about an axis passing through the stationary foot 9, and thus exit the box 2.

The panel 8 comprises a serpentine copper pipe 12 running through the panel in several vertical sections. Three electronic board cradles 13, 14 and 15 can be distinguished, generally corresponding to three vertical sections. A final vertical section comprises two feeders 16 and 17. A retractable foot 18 is provided to keep the panel stationary inside the box and to be deployed by touching the ground when the panel 8 is open.

FIG. 2 shows two pipes 19 and 20 very schematically in dotted lines, one between the water inlet to the boiler and the bottom of the foot 9, the other between the water outlet from the boiler and the bottom of the foot 9. Hoses are provided to connect the pipes 19 and 20 to the inlet and outlet of the loop formed by the pipe 12. These two pipes 19 and 20, forming part of the water circuit, pass through a radiator 21 located on the upper part of the boiler. In this way, the heat coming from the electronic boards and rising through the chimney effect comes into contact with the radiator to heat the pipes 19 and 20. It thus performs a form of natural preheating. Fans can be provided under the radiator, for example in contact with the lower surface of the radiator, to promote air circulation.

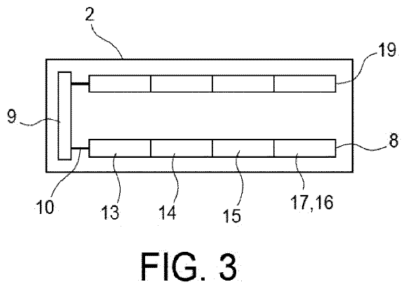

FIG. 3 is a schematic cross-sectional view of the top of the boiler. Inside the box 2, the foot 9 is secured to the box and remains stationary. The panel 8 is shown with four sections 13, 14, 15 and the assembly 16 and 17. Another panel 22 is also visible, constructed in the same way as the panel 8, and can be extended outwards on the opposite side to the panel 8. However, the same foot 9 or a narrow foot, equipped with the same hinges or other types of hinges, in particular sliding hinges, can be envisaged, allowing the panel 22 to be deployed on the same side as the panel 8. In this way, both panels can be accessed from the same side during maintenance operations.

More than two panels can also be arranged inside the same box.

The panel arrangement shown in FIG. 3 creates empty vertical columns wherein air circulates within the box. This layout encourages circulation from bottom to top. And the vertical arrangement of the pipes, with a parallel round trip, ensures better temperature distribution inside the box.

The vertical orientation of the panels facilitates the placement of electronic boards, and allows certain temperature-sensitive components to be placed at the bottom.

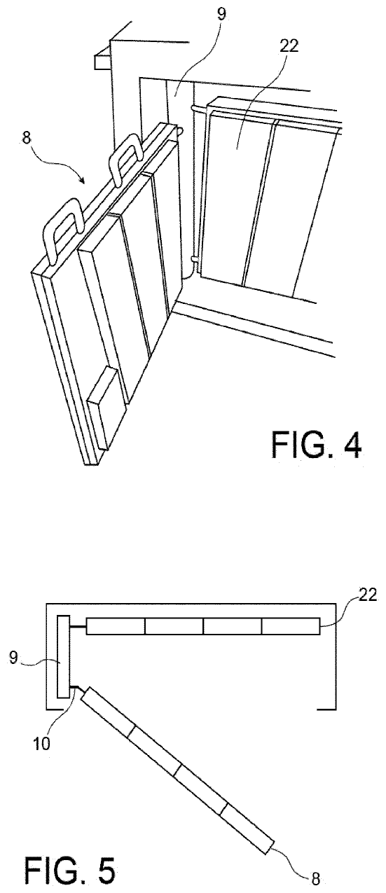

FIG. 4 is a perspective view of the open panel 8. The foot 9 and the panel 22 are still visible.

FIG. 5 is a schematic top cross-sectional view of the boiler according to the situation of FIG. 4. Inside the box 2, the stationary foot 9 is visible.

The panel 8 is deployed toward the outside of the box. Depending on the hinges used, the panel can be fully or partially deployed outside the box 2.

We can now describe the construction of a panel.

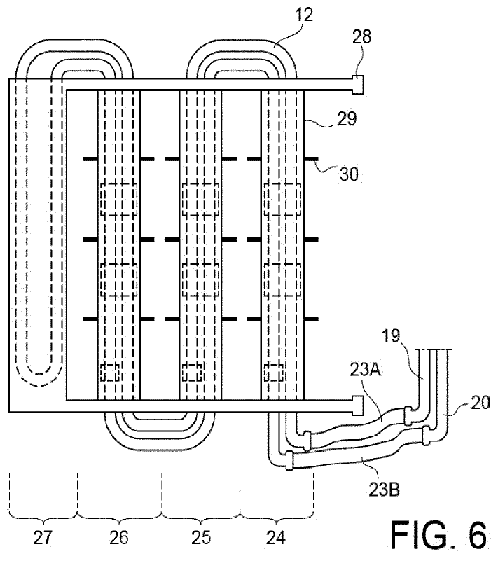

FIG. 6 is a schematic view of the copper pipe 12 arranged in a serpentine pattern in the panel. This pipe 12 is fed by the inlet pipe 19 via a hose 23A. And the return pipe 12 feeds the outlet pipe 20 or a second panel 22 via the hose 23B.

The forward run of the pipe 12 starts from the hose 23A, rises vertically in the vertical section 24, turns and returns downwards in the vertical section 25. The route then continues via the vertical section 26 to the vertical section 27.

The pipe 12 then undergoes a bend and returns in the opposite direction, parallel to the first run. Thus, in each section, the pipe 12 passes twice: in one direction and then in the other.

With the boiler according to the invention, water circulation between the vertical sections takes place in such a way as to homogenize the overall temperature on a panel.

In the example shown in FIG. 6, the vertical section 27 is designed to accommodate two feeders 16 and 17. The distance between the forward pipe and the return pipe in the vertical section 27 is slightly greater than in other vertical sections.

The invention uses copper pipes of conventional plumbing dimensions, so that the boiler can be directly connected to the water distribution network.

FIG. 6 also shows a frame 28 to hold the assembly rigidly in place. Each vertical section 24-26 is equipped with two metal blocks 29 framing the two pipes 12.

We will now describe the system for pressing a server or electronic board on the metal block, so as to ensure effective contact between the electronic components likely to generate heat and the metal block, good contact being synonymous with good heat transmission to the pipe 12.

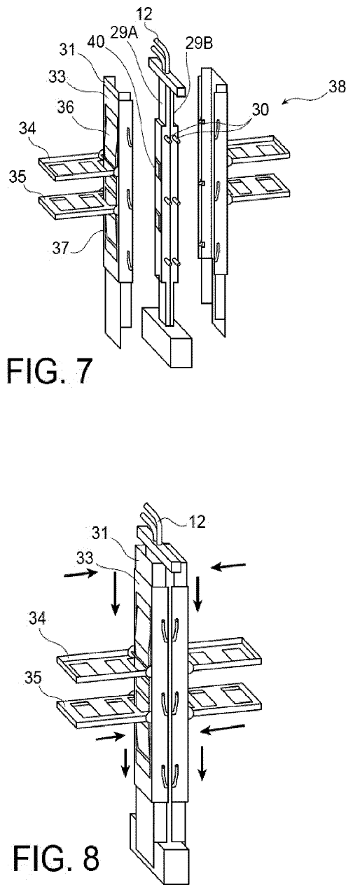

FIGS. 7, 8 and 9 show the progression of the server's pressing movement onto the metal block.

FIG. 7 shows the two metal blocks 29A and 29B sandwiching the copper pipe 12. The cradle 31 is kept parallel to but at a distance from the metal block 29A. As will be seen later, the server is positioned inside the cradle, facing the metal block.

Advantageously, a slide 33 rests against the cradle 31. In other words, the slide 33 conforms to the external shape (with the server inside) of the cradle, that is, the back and side walls of the cradle.

FIG. 10 shows in slightly greater detail the succession of layers between the slide and the metal block. The pipe 12 is held in grooves inside the metal block 29A. The server 32 is held stationary in the cradle 31 between the back of the cradle and the metal block. The electronic components 39 of the server are designed to be pressed against the receptacle 40 (visible in FIG. 7) of the metal block. The cradle comprises two side walls 31A and 31B. The wall 31A comprises a straight groove 31C facing the support member 30. When the support member 30 engages the straight groove 31C, the electronic component 39 faces the receptacle 40. The straight groove 31C is a guide for positioning the electronic component exactly opposite a predefined area of the metal block. Once the support member 30 is engaged in the right-hand groove 31C, the movement of the electronic component toward the metal block is carried out by keeping the electronic component facing its predefined zone. The same pair of straight grooves and support members is used on the opposite wall 31B. Other pairs are provided on the walls. FIG. 7 shows three pairs on each wall. With such a straight groove 31C, once the cradle is engaged in the support members 30, pressure on the back of the cradle causes a linear displacement of the server toward the metal block.

The slide 33 in FIG. 10 also comprises two side walls 33A and 33B. The side wall 33A comprises an oblique groove 33C, the inlet to which is designed to be positioned opposite the support member 30 before the slide 33 slides. The same pair of oblique grooves and support members is used on the opposite wall 33B. Other pairs are provided on the walls. FIG. 7 shows three pairs on each wall.

With such an oblique groove 33C, a downward movement of the slide in FIG. 10 causes the slide to slide relative to the cradle 31, which remains at the same height due to the support members 30. The slide can be lowered until the support member 30 abuts the upper end of the oblique groove 33C. The downward movement of the slide presses the cradle against the metal block 29A. The upper end of the oblique groove may comprise a curved portion to prevent the support member 30 from escaping.

FIG. 7 shows two cam handles 34 and 35 associated with springs 36 and 37 designed to press the back of the cradle toward the metal block 29A.

FIG. 7 also shows another assembly 38 comprising a slide, a cradle and a server designed to be pressed against the metal block 29B.

In FIG. 8, using cam handles 34 and 35, a user presses the slide 33 and cradle 31 assembly onto the metal block 29A, and the assembly 38 onto the metal block 29B, taking care to insert the support members 30 into the straight and oblique grooves. This is followed by a longitudinal displacement movement to slide the slide 33 downwards, bringing the support members up into the oblique grooves, with the support members sinking further into the straight grooves.

The sliding movement of the slide in relation to the cradle constitutes a first pressing.

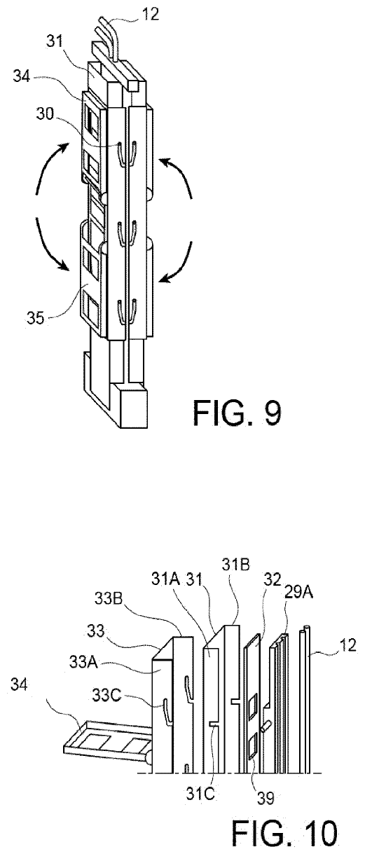

A second pressing is obtained after locking the cam handles. To do this, the cam handles are folded back along the slide as shown in FIG. 9.

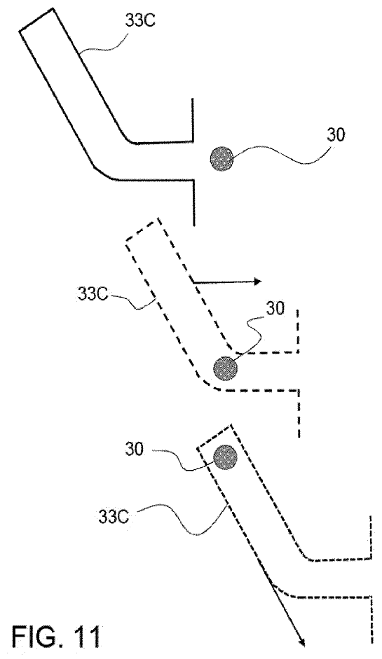

FIG. 11 is a schematic view showing the movement of the oblique groove 33C relative to the support member 30 of the metal block. This support member 30 is considered to remain stationary with respect to the movement of the slide 41, which movement is identical to that of the groove 33C. When the slide and cradle assembly 33/31 is separated from the metal block 29A, the groove 33C is at a distance from the support member 30, as shown in the first part of FIG. 11. The movement consisting in associating the slide and cradle assembly 33/31 with the metal block 29A comprises a first horizontal movement (as shown in FIGS. 10 and 11). During this first movement, the support member 30 is inserted into a horizontal, straight part of the groove 33C, as shown in the second part of FIG. 11. Then, the slide, and therefore the groove, performs both a horizontal and a vertical downward movement (as shown in FIGS. 10 and 11), so that the support member 30 is inserted into the oblique part of the groove 33C.

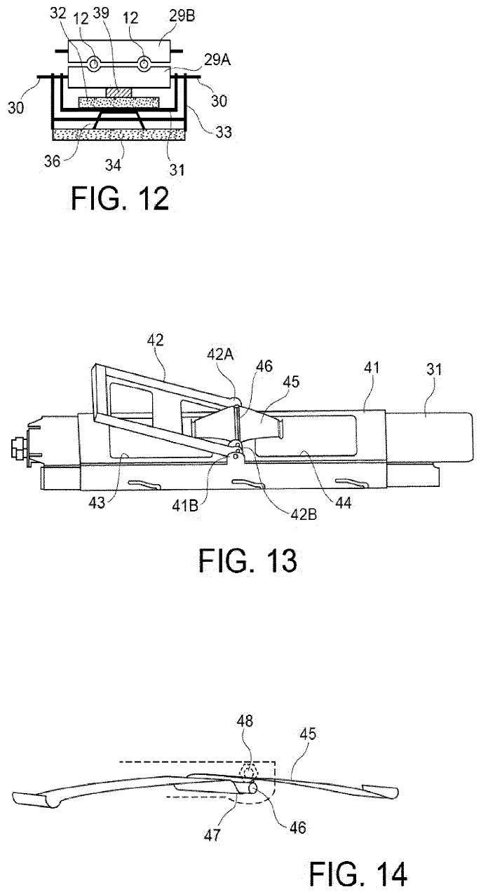

FIG. 12 is a cross-sectional view showing the cradle 31 pressed against the metal block 29A.

The electronic component 39 is in contact with the metal block 29A. The support members 30 hold the cradle 31 stationary. When the electronic component 39 heats up, the heat is effectively transmitted to the pipes 12 that carry the water.

The spring 36 presses the cradle 31 toward the metal block to keep the electronic component 39 pressed against this metal block 29A. In FIG. 12, the handle 34 is in the locked position.

Although FIGS. 7 to 12 relate to embodiments with slides fitted with double cam handles, these embodiments can be adopted by the person skilled in the art with a single cam handle per slide without departing from the scope of the invention.

FIG. 13 shows the cradle 31 whereupon a slide 41 fitted with a single cam handle 42 is mounted. The slide 41 can slide longitudinally on the cradle 31. Openings 43 and 44 are made in the slide so that the back of the cradle 31 is exposed in the zones defined by the openings.

The cam handle 42 comprises cams 42A and 42B which are pivotally attached to eyelets 41A and 41B, respectively, on the slide 4L. The leaf spring 45, which has a domed shape, engages a rod 46 connecting the two cams 42A and 42B. The rod 46 is inserted into a rib 47 positioned at the center of the leaf spring 45.

When the cam handle 42 is in the high position, as in FIG. 13 and FIG. 8, the rod 46 is also in the high position and the ends of the leaf spring 45 do not exert significant pressure on the back of the cradle 31 at the openings 43 and 44. In this position, the spring ends may not even be in contact with the cradle 31.

When the cam handle 42 is in the locked position as shown in FIG. 9 and FIG. 14, the rod 46 is in the low position, pressing both ends of the leaf spring 45 against the back of the cradle 31.

The rod 46 can be moved from a high position to a low position, and vice versa, as this rod connecting the two cams 42A and 42B is not located in the axis of rotation 48 of the cams 42A and 42B. The openings 43 and 44 are sufficiently large, and the ends of the leaf spring are shaped so that when the rod 46 is rotated, the spring can undergo slight sliding movements without hindrance. In particular, the ends of the leaf spring have a rounded shape.

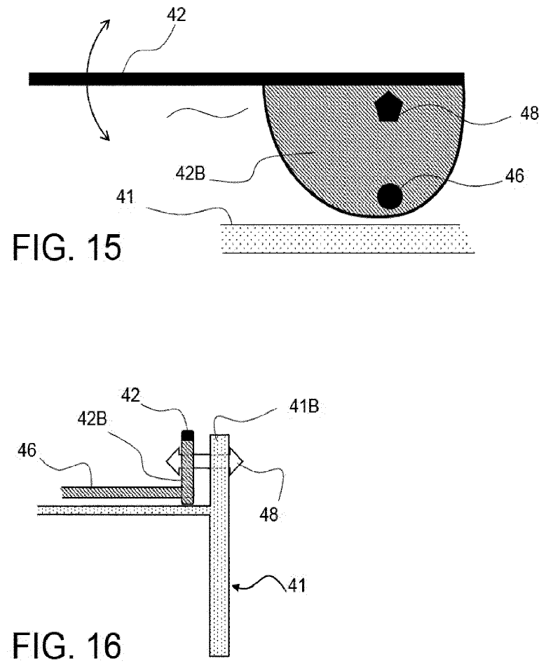

FIGS. 15 and 16 show, in a little more detail, the cam mechanism used to press the springs against the cradle 31. FIG. 15 shows the handle 42 with its cam 42B at one end. This cam is the equivalent of a deformed semicircle. The handle is designed to pivot about an axis of rotation 48 spaced apart from the attachment point of the rod 46. Thus, on the cam 42B, the rotation axis 48 and the rod 46 are spaced so that when the handle is in the open position, the rod 46 is at a position further away from the slide 41 than when the handle is in the closed position. FIG. 15 shows the handle in the closed position, with the rod 46 in the low position, close to the slide 4L. The distance between the rotation axis 48 and the rod 46 defines the optimum pressure to be applied to the spring 45. The same principle as disclosed above is applied to the cam 42A.

FIG. 16 shows a cross-sectional view of the components shown in FIG. 15. The cam 42B is held pivotally by the pin 48, which is secured to the eyelet 41B. The movement of the handle 42 moves the rod 46 away from or toward the part of the slide 41 located under the cam 42B. When the rod 48 approaches the slide, the spring 45 bears on the cradle 31.

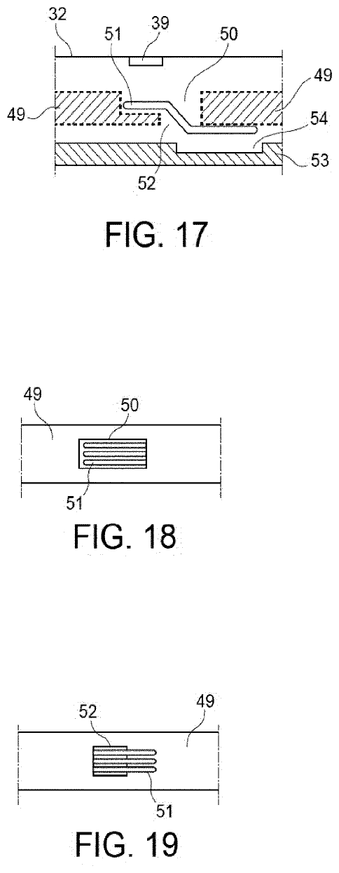

Heat pipes can be integrated into the metal block to better diffuse heat into and through the metal block and recover it from the water circuit. FIG. 17 shows an example embodiment of heat pipes integrated into a modular block 49 according to the invention. The electronic board 32 with the component 39 can be seen. This modular block 49 is a removable part designed to be attached to a stationary block 53, together forming the metal block. The modular block 49 comprises an opening 50 to receive the electronic component 39. Heat pipes 51 are arranged through the modular block 49. These heat pipes 51 are rods with one end visible in the upper opening 50, as shown in FIG. 18.

The second ends of the rods 51 appear on the underside of the modular block 49, as shown in FIG. 19. This FIG. 19 shows the rear surface of the modular block 49, with the lower opening 52 allowing the heat pipes 51 to pass through the modular block 49. The stationary block 53 is designed to come into contact with the underside of the modular block 49 and with the heat pipes 51. The stationary block 53 can comprise recesses 54 to accommodate the heat pipes 51.

The function of the heat pipes 51 is to efficiently transfer the heat generated by the electronic component 39 to the stationary block 53, and then to a water circuit.

Of course, the invention is not limited to the examples disclosed above. Many modifications can be made to these examples without departing from the scope of the present invention as disclosed.

1. A system for pressing an electronic board onto a metal block provided with one or more side support members; the system comprising:
a cradle housing the electronic board intended to be pressed against a surface of the metal block, the cradle comprising side walls provided with straight grooves capable of engaging with the support members of the metal block when the cradle is pressed against the surface of the metal block;
a slide arranged on the back of the cradle, this slide comprising side walls provided with oblique grooves capable of engaging with the support members; these oblique grooves being arranged in such a way that a longitudinal sliding movement of the slide relative to the cradle moves the cradle sideways so as to press the electronic board onto the metal block; and
at least one cam handle for applying pressure to press the electronic board against the metal block.

2. The system according to claim 1, characterized in that the slide comprises an opening in the back of the cradle so that a locking of the cam handle presses the cradle against the metal block.

3. The system according to claim 1, characterized in that the slide comprises a spring arranged between the cam handle and the back of the cradle.

4. The system according to claim 3, characterized in that the spring is a leaf capable of pressing the cradle against the metal block when the cam handle is locked.

5. The system according to claim 4, characterized in that the leaf has a curvature; the two ends bearing directly on the back of the cradle; the center of the leaf comprising a rib wherein a rod is inserted which is connected to the cam of the cam handle; the rod being off the pivot axis of the cam handle.

6. The system according to claim 5, characterized in that the cam handle comprises two cams connected together by the rod, the two cams being arranged on both sides of the leaf.

7. The system according to claim 1, characterized in that the cam handle comprises a pivot axis contained in a plane parallel to the back of the cradle the handle being pivotally connected to eyelets on the slide.

8. The system according to claim 1, characterized in that the slide has a “U”-shaped cross-section suitable for nesting the cradle in this slide.

9. The system according to claim 1, characterized in that the cradle has a “U”-shaped cross-section for housing the electronic board and for nesting the metal block into this cradle.

10. The system according to claim 1, characterized in that the oblique groove is an opening in the side wall of the slide, this opening going from a point on the wall, away from the free edge, down obliquely in a linear or non-linear manner until it opens onto the free edge of the side wall of the slide.

11. The system according to claim 1, characterized in that the straight groove is an opening in the side wall of the cradle, this opening being perpendicular to a plane containing the electronic board and opening onto the free edge of the cradle side wall.

12. The system according to claim 1, characterized in that the metal block is a longitudinal body and the system further comprises at least two side support members attached to the metal block but extending outside the metal block on the same line but in two opposite directions.

13. The system according to claim 1, characterized in that the metal block comprises at least one water circulation pipe for recovering heat generated by the electronic board.

14. The system according to claim 1, characterized in that the metal block comprises a protuberance and/or a cavity able to match the external shape of an electronic component contained on the electronic board.

15. The system according to claim 1, characterized in that the metal block consists of at least two parts, a stationary block and a modular block adapted to a given electronic board.

16. A method of securing an electronic board to a metal block, the electronic board being contained in a cradle equipped with a slide, this metal block being provided with one or more side support members; the method comprising the following steps:
pressing the cradle onto the metal block, the cradle comprising side walls provided with straight grooves which engage with the support members of the metal block, and the slide comprising side walls provided with oblique grooves which also engage with the support members of the metal block;
longitudinal sliding movement of the slide in relation to the cradle, so that the support members run in the oblique grooves and the electronic board is pressed against the metal block; and
locking a cam handle for applying pressure to press the electronic board against the metal block.
